(19) United States
(12) Patent Application Publication
(10) Pub. No.: US 2011/0214812 A1
(43) Pub. Date: Sep. 8, 2011

(54) GAS DISTRIBUTING MEANS AND SUBSTRATE PROCESSING APPARATUS INCLUDING THE SAME

(75) Inventors: MYUNG-GON SONG, Jeollanam-do (KR); JUNG-RAK LEE, Gyeonggi-do (KR); JAE-CHUL DO, Daegu (KR); BU-IL JEON, Gyeonggi-do (KR); SEONG-DAE CHOI, Seoul (KR)

(73) Assignee: JUSUNG ENGINEERING CO., LTD., Gyeonggi-do (KR)

(21) Appl. No.: 13/043,055

(22) Filed: Mar. 8, 2011

(30) Foreign Application Priority Data
Mar. 8, 2010 (KR) 10-2010-0020303

(51) Int. Cl. C23F 1/08; C23C 16/455; C23C 16/458; C23C 16/50; B67D 7/06; B23P 17/00

(52) U.S. Cl. 156/345.33; 118/728; 118/723 E; 222/129; 29/890.1

(57) ABSTRACT

A substrate processing apparatus includes a process chamber having a chamber lid and a chamber body to provide a reaction space and a gas distributing means including a plate and an injection part in the process chamber. The injection part includes a plurality of through holes in the plate and a discharge portion capable of being in fluid communication with the plurality of through holes. The discharge portion has a matrix shape and provides a space where a plasma is discharged. The apparatus additionally includes a susceptor in the process chamber. The susceptor faces the gas distributing means.

This application claims the benefit of Korean Patent Application No. 10-2010-0020303, filed on Mar. 8, 2010, which is hereby incorporated by a reference in its entirety.

### TECHNICAL FIELD

The present disclosure relates to a gas distributing means, and more particularly, to a gas distributing means having a discharging portion where a process gas is supplied and a plasma is discharged and a substrate processing apparatus including the gas distributing means.

### BACKGROUND

In general, a semiconductor device, a display device and a solar cell are fabricated through a depositing process where a thin film is formed on a substrate, a photolithographic process where a thin film is selectively exposed and shielded by a photosensitive material and an etching process where a thin film is selectively removed. Among the fabricating processes, the deposition process and the etching process are performed in a substrate processing apparatus under an optimum vacuum state using a plasma.

FIG. 1 is a cross-sectional view showing a substrate processing apparatus according to the related art. In FIG. 1, a substrate processing apparatus 10, for example, a plasma enhanced chemical vapor deposition (PECVD) apparatus, includes a process chamber 12 providing a reaction space, a susceptor 16 in the process chamber 12 and having a substrate 14 thereon and a gas distributing means 18 supplying a process gas to the substrate 14.

The substrate processing apparatus 10 further includes an edge frame 20 on an inner wall of the process chamber 12 for preventing deposition of a thin film on an edge portion of the substrate 14, a gas inlet pipe 22 where the process gas is transmitted to the gas distributing means 18 through a chamber lid 12a, a gate valve (not shown) where the substrate 14 is inputted and outputted and an exhaust port 24.

When the susceptor 16 moves up to be located at a process position, the edge frame 20 blocks the edge portion of the substrate 14 to prevent formation of the thin film on the edge portion of the substrate 14. A reaction gas in the reaction space is outputted through the exhaust port 24 so that a vacuum state of the reaction space can be controlled. A vacuum pump (not shown) is connected to the exhaust port 24.

The process chamber 12 includes the chamber lid 12a and a chamber body 12b combined to the chamber lid 12a with an O-ring (not shown) interposed therebetween. The gate distributing means 18 is electrically connected to the chamber lid 12a. A radio frequency (RF) power supply 26 supplying an RF power is connected to the chamber lid 12a and the susceptor 16 is grounded. A matcher 30 for impedance matching is connected between the chamber lid 12a and the RF power supply 26. Accordingly, the chamber lid 12a and the susceptor 16 function as a plasma upper electrode and a plasma lower electrode, respectively. When the process gas is supplied to the reaction space, the process gas is activated or ionized by the plasma upper electrode and the plasma lower electrode.

The susceptor 16 includes a heater 26 therein for heating up the substrate 14, and a supporting shaft 28 for moving the susceptor 16 is connected to a rear surface of the susceptor 16. The gas distributing means 18 is suspended by the chamber lid 12a, and a buffer space 32 accommodating the process gas inputted through the gas inlet pipe 22 is formed between the gas distributing means 18 and the chamber lid 12a. The gas inlet pipe 22 is formed to penetrate a central portion of the chamber lid 12a. A baffle (not shown) is formed at a position of the buffer space 32 corresponding to the gas inlet pipe 24 to diffuse the process gas transmitted through the gas inlet pipe 24 uniformly. A plurality of injection holes 34 for injecting the process gas toward the susceptor 16 are formed in the gas distributing means 18.

The gas distributing means 18 of the substrate processing apparatus 10 will be illustrated in detail hereinafter. FIGS. 2 and 3 are plan and cross-sectional views, respectively, showing a gas distributing means of a substrate processing apparatus according to the related art. In FIG. 2, the gas distributing means 18 includes a plate 18a and a plurality of injection holes 34 in the plate 18. Each of the plurality of injection holes 34 penetrates the plate 18a and includes an inlet portion 34a, an orifice portion 34b and an injection portion 34c.

The process gas temporarily accommodated by the buffer space 32 (of FIG. 1) is inputted through the inlet portion 34a. The orifice portion 34b is disposed under the inlet portion 34a and is in fluid connection with the inlet portion 34a. A diameter of the orifice portion 34b is smaller than a diameter of the inlet portion 34a. The injection portion 34c is disposed under the orifice portion 34b and is in fluid connection with the orifice portion 34b. The injection portion 34c sprays the process gas into the reaction space. The gas distributing means 18 having the plurality of injection holes 34 is obtained by perforating the plate 18a. The diameters of inlet portion 34a and the injection portion 34c are about 2 mm and about 8 mm, respectively. In addition, the diameter of the orifice portion 34b is about 0.5 mm

The thin film formed on the substrate 14 (of FIG. 1) in the substrate processing apparatus 10 (of FIG. 1) is required to have a uniform thickness and a uniform property. The uniform thickness and the uniform property of the thin film are influenced by a uniform supply of the process gas sprayed onto the substrate 14. To supply the process gas uniformly, the plurality of injection holes 34 are uniformly distributed in the plate 18a.

In FIG. 3, the distributing means 18 is viewed from a bottom surface thereof and the inlet portion 34a is designated by a dotted line. The plurality of injection holes 34 penetrating the plate 18a are disposed to have a uniform gap distance between two adjacent injection holes 34.

The substrate processing apparatus 10 according to the related art has problems. Firstly, although the inlet portion 34a and the injection portion 34c are easily manufactured due to a relatively greater diameter thereof, the orifice portion 34b is not easily manufactured due to a relatively smaller diameter (for example, about 0.5 mm) thereof.

Secondly, a plasma density in a first region corresponding to each of the plurality of injection holes 34 is greater than a plasma density in a second region corresponding to a gap between adjacent injection holes 34. The plasma is discharged between the gas distributing means 18 and the susceptor 16. Since the process gas is directly supplied to the first region corresponding to each of the plurality of injection holes 34, the plasma density in the first region is relatively high. However, since the process gas is supplied to the second region corresponding to the gap between the adjacent injection holes 34 by a lateral diffusion of the process gas supplied through the plurality of injection holes 34, the plasma density in the second region is relatively low. As a result, the plasma has a non-uniform plasma density and the thin film formed on the substrate 14 has a non-uniform thickness and a non-uniform property.

### SUMMARY

Accordingly, the present disclosure is directed to a gas distributing means and a substrate processing apparatus including the same that substantially obviate one or more of the problems due to limitations and disadvantages of the related art.

An object of the present disclosure is to provide a gas distributing means including a discharge portion of a matrix shape that increases a spray area of a process gas and provides a discharge space for a plasma and a substrate processing apparatus including the gas distributing means.

Another object of the present disclosure is to provide a gas distributing means where the number of a plurality of through holes transmitting a process gas is reduced due to induction of lateral diffusion of the process gas in a discharge portion of a matrix shape and a substrate processing apparatus including the gas distributing means.

To achieve these and other advantages and in accordance with the purpose of the present invention, as embodied and broadly described, a substrate processing apparatus includes: a process chamber including a chamber lid and a chamber body to prove a reaction space; a gas distributing means including a plate and an injection part in the process chamber, the injection part including a plurality of through holes in the plate and a discharge portion capable of being in fluid communication with the plurality of through holes, the discharge portion having a matrix shape and providing a space where a plasma is discharged; and a susceptor in the process chamber, the susceptor facing the gas distributing means.

In another aspect, a substrate processing apparatus includes: a process chamber including a chamber lid and a chamber body to provide a reaction space; a plurality of plasma source electrodes on an inner surface of the chamber lid; a plurality of first gas distributing means in the plurality of plasma source electrodes, respectively, at least one of the plurality of first gas distributing means including a first buffer space capable of accommodating a first process gas, a plurality of first through holes capable of being in fluid communication with the first buffer space and a first discharge portion capable of being in fluid communication with the plurality of first through holes, the first discharge portion having a matrix shape and providing a first space where a first plasma of the first process gas is discharged; and a susceptor in the process chamber, the susceptor facing the plurality of plasma source electrodes.

In another aspect, a gas distributing means for a substrate processing apparatus includes: a plate including first and second surfaces; and an injection part including a plate and an injection part, wherein the injection part has a plurality of through holes extending from the first surface toward the second surface in the plate and a discharge portion capable of being in fluid communication with the plurality of through holes, the discharge portion having a matrix shape and providing a space where a plasma is discharged.

In another aspect, a method of manufacturing a gas distributing means for a substrate processing apparatus includes: providing a plate having first and second surfaces; forming a plurality of first through holes extending from the first surface toward the second surface; forming a plurality of second through holes capable of being in fluid communication with the plurality of first through holes; and forming a discharge portion capable of being in fluid connection with the plurality of second through holes, the discharge portion having a matrix shape and providing a space where a plasma is discharged.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention.

In the drawings:

FIG. 1 is a cross-sectional view showing a substrate processing apparatus according to the related art;

FIG. 2 is a plan view showing a gas distributing means of a substrate processing apparatus according to the related art;

FIG. 3 is a cross-sectional view showing a gas distributing means of a substrate processing apparatus according to the related art;

FIG. 4 is a cross-sectional view showing a substrate processing apparatus according to a first embodiment of the present invention;

FIG. 5A is a broken perspective view showing gas distributing means according to a first embodiment of the present invention;

FIG. 5B is a broken perspective view showing gas distributing means according to a second embodiment of the present invention;

FIG. 6 is a plan view showing a top surface of a gas distributing means according to a first embodiment of the present invention;

FIG. 7 is a plan view showing a bottom surface of a gas distributing means according to a first embodiment of the present invention;

FIG. 8 is a cross-sectional view showing a substrate processing apparatus according to a third embodiment of the present invention;

FIG. 9 is a plan view showing a bottom surface of a chamber lid of a substrate processing apparatus according to a third embodiment of the present invention;

FIG. 10 is a perspective view showing a chamber lid of a substrate processing apparatus according to a third embodiment of the present invention;

FIG. 11 is an exploded perspective view showing an insulating means and a first gas distributing means of a plasma source electrode according to a third embodiment of the present invention;

FIG. 12 is a plan view showing a top surface of a first gas distributing means of a plasma source electrode according to a third embodiment of the present invention;

FIG. 13 is a plan view showing a bottom surface of a first gas distributing means of a plasma source electrode according to a third embodiment of the present invention;

FIG. 14 is a perspective view showing a second gas distributing means of a protruding electrode according to a third embodiment of the present invention;

FIG. 15 is a plan view showing a top surface of a second gas distributing means of a protruding electrode according to a third embodiment of the present invention; and

FIG. 16 is a plan view showing a bottom surface of a second gas distributing means of a protruding electrode according to a third embodiment of the present invention.

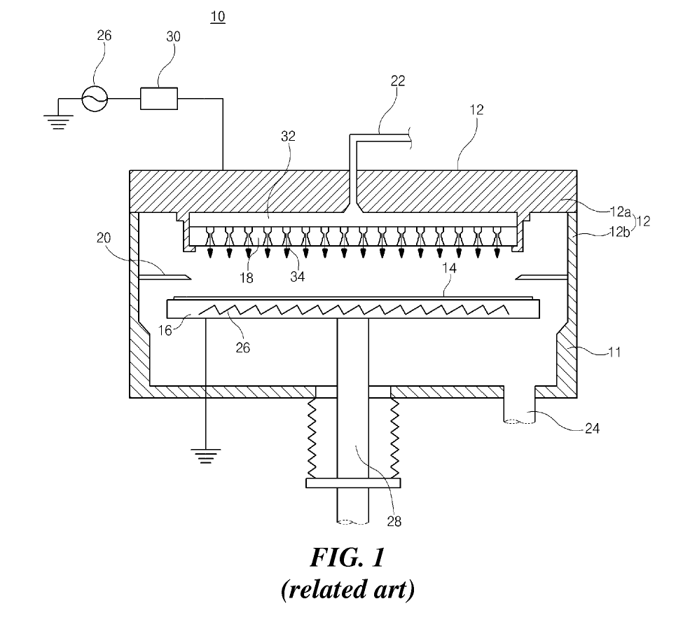

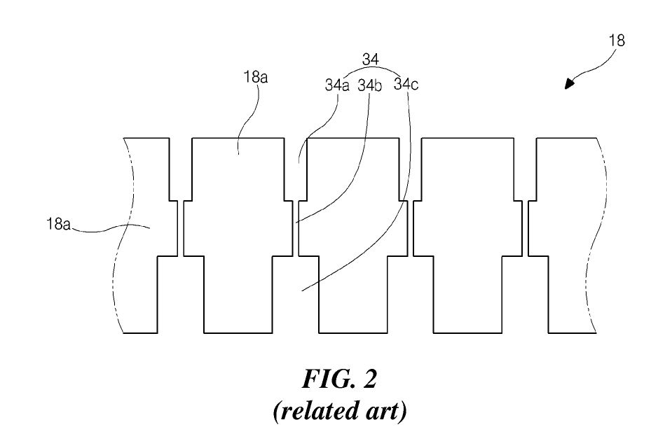

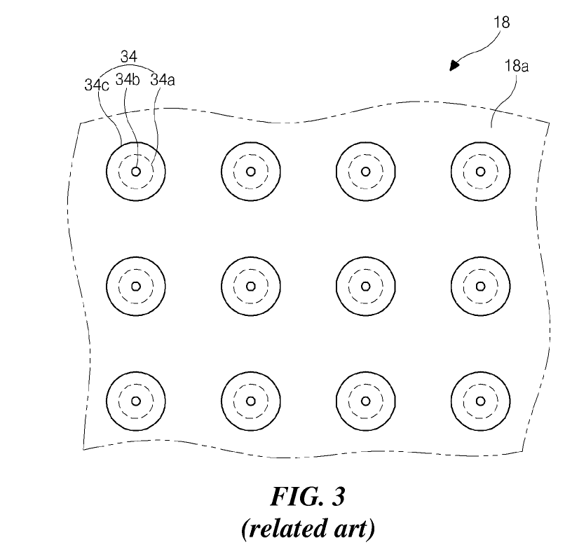

### DETAILED DESCRIPTION OF THE PREFERRED EMBODIMENTS

Reference will now be made in detail to embodiments which are illustrated in the accompanying drawings. Wherever possible, similar reference numbers will be used to refer to the same or similar parts.

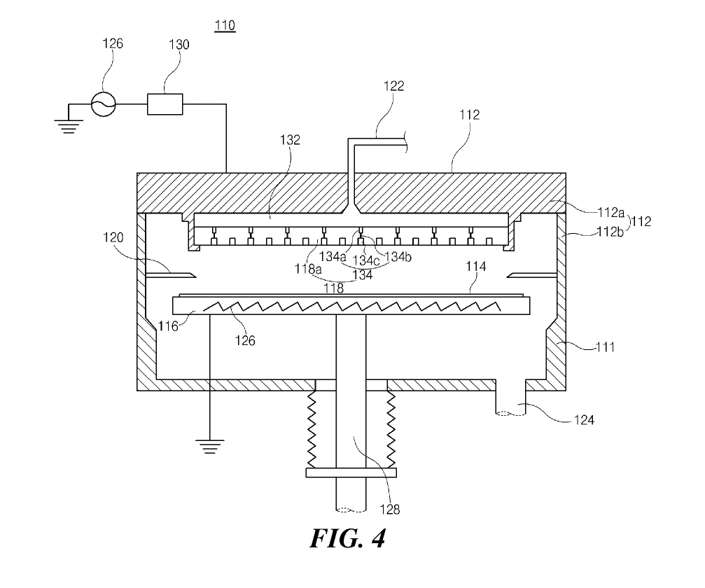

FIG. 4 is a cross-sectional view showing a substrate processing apparatus according to a first embodiment of the present invention.

In FIG. 4,a substrate processing apparatus 110 such as a plasma enhanced chemical vapor deposition (PECVD) apparatus includes a process chamber 112 providing a reaction space, a susceptor 116 in the process chamber 112 and having a substrate 114 thereon and a gas distributing means 118 supplying a process gas to the substrate 114. The process chamber 112 includes the chamber lid 112a and a chamber body 112b combined to the chamber lid 112a with an O-ring (not shown) interposed therebetween.

The substrate processing apparatus 110 further includes an edge frame 120 on an inner wall of the process chamber 112 for preventing deposition of a thin film on an edge portion of the substrate 114, a gas inlet pipe 122 where the process gas is transmitted to the gas distributing means 118 through a chamber lid 112a, a gate valve (not shown) where the substrate 114 is inputted and outputted and an exhaust port 124.

When the susceptor 116 moves up to be located at a process position, the edge frame 120 blocks the edge portion of the substrate 114 to prevent formation of the thin film on the edge portion of the substrate 114. A reaction gas in the reaction space is outputted through the exhaust port 124 so that a vacuum state of the reaction space can be controlled. A vacuum pump (not shown) may be connected to the exhaust port 124.

The gate distributing means 118 is electrically connected to the chamber lid 112a. A radio frequency (RF) power supply 126 supplying an RF power is connected to the chamber lid 112a and the susceptor 116 is connected to a ground line to be grounded. A matcher 130 for impedance matching is connected between the chamber lid 112a and the RF power supply 126. Accordingly, the chamber lid 112a and the susceptor 116 function as a plasma upper electrode and a plasma lower electrode, respectively. When the process gas is supplied to the reaction space, the process gas is activated or ionized by the plasma upper electrode and the plasma lower electrode.

The susceptor 116 may include a heater 126 therein for heating up the substrate 114, and a supporting shaft 128 for moving the susceptor 116 up and down is connected to a rear surface of the susceptor 116. The gas distributing means 118 is suspended by the chamber lid 112a, and a buffer space 132 capable of temporarily accommodating the process gas inputted through the gas inlet pipe 122 is formed between the gas distributing means 118 and the chamber lid 112a. The gas inlet pipe 122 is formed to penetrate a central portion of the chamber lid 112a. A baffle (not shown) may be formed at a position of the buffer space 132 corresponding to the gas inlet pipe 124 to diffuse the process gas transmitted through the gas inlet pipe 124 uniformly.

The gas distributing means 118 includes a plate 118a and an injection part 134 penetrating the plate 118a. In addition, the injection part 134 includes a plurality of first through holes 134a, a plurality of second through holes 134b and a discharge portion 134c.

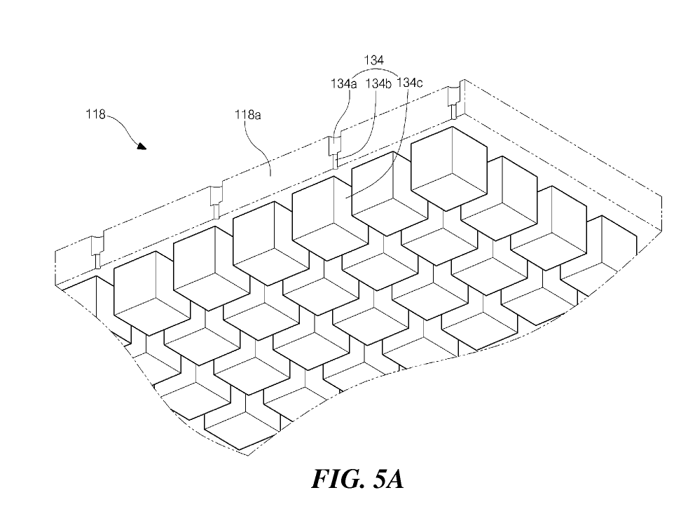

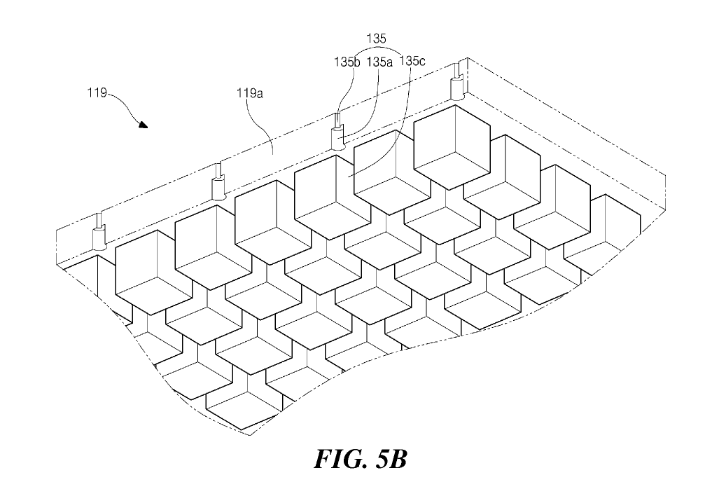

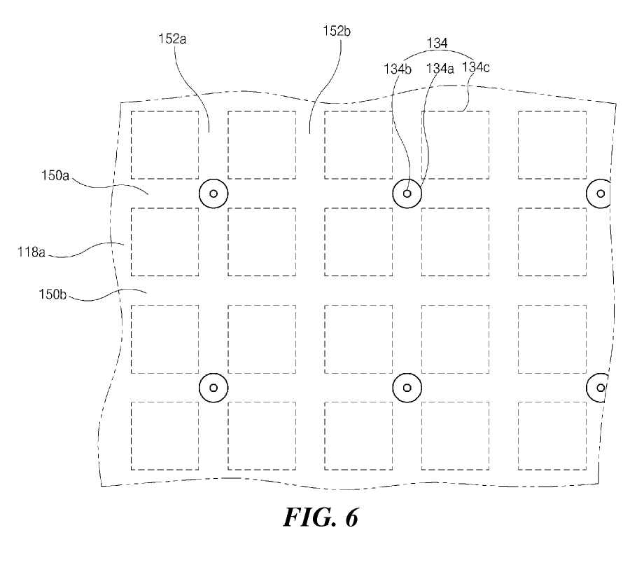

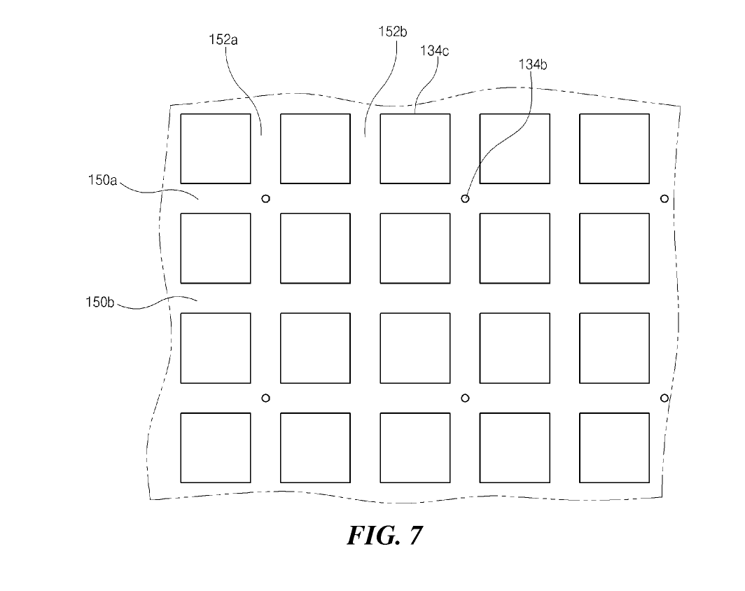

FIGS. 5A and 5B are broken perspective views showing gas distributing means according to first and second embodiments, respectively, of the present invention, and FIGS. 6 and 7 are plan views showing top and bottom surfaces, respectively, of a gas distributing means according to a first embodiment of the present invention.

In FIG. 5A, the gas distributing means 118 includes the plate 118a having a first surface contacting the buffer space 132 (of FIG. 4) and a second surface facing the susceptor 116 (of FIG. 4). The plate 118a may have the same shape as the susceptor 116, for example, a rectangular shape or a circular shape.

The injection part 134 includes the plurality of first through holes 134a extending from the first surface toward the second surface of the plate 118a, the plurality of second through holes 134b that are coupled with the plurality of first through holes 134a, respectively, and the discharge portion 134c that is coupled with the plurality of second through holes 134b and extends to the second surface of the plate 118a.

The process gas transmitted through the gas inlet pipe 122 is capable of being temporarily accommodated in the buffer space 132, and the process gas in the buffer space 132 is transmitted to the plurality of first through holes 134a. The plurality of first through holes 134a are uniformly distributed in the plate 118a such that every adjacent two of the plurality of first through holes 134a are spaced apart from each other by the same gap distance. The plurality of second through holes 134b may be in fluid communication with the plurality of first through holes 134a, respectively, and a diameter of at least one of the plurality of second through holes 134b may be smaller than a diameter of at least one of the plurality of first through holes 134a. The discharge portion 134c of a matrix shape is coupled with the plurality of second through holes 134b and provides a space where a plasma is discharged.

In another embodiment, the positions of the plurality of first through holes and the plurality of second through holes may be replaced. In other words, a diameter of at least one of the plurality of second through holes may be greater than a diameter of at least one of the plurality of first through holes. In FIG. 5B, a gas distributing means 119 includes a plate 119a and an injection part 135 penetrating the plate 119a, and the injection part 135 includes a plurality of second through holes 135b extending from a first surface of the plate 119a toward a second surface of the plate 119a, a plurality of first through holes 135a that are coupled with the plurality of second through holes 135b, respectively, and a discharge portion 135c of a matrix shape that is coupled with the plurality of first through holes 135a and extends to the second surface of the plate 119a.

In FIG. 6, the plurality of first through holes 134a are uniformly distributed in the plate 118a such that every adjacent two of the plurality of first through holes 134a are spaced apart from each other by the same gap distance. In addition, at least one of the plurality of second through holes 134b is connected to a central portion of at least one of the plurality of first through holes 134a. A plurality of first horizontal grooves 150a and a plurality of first vertical grooves 152a, a plurality of second horizontal grooves 150b and a plurality of second vertical grooves 152b of the discharge portion 134c are designated by a dotted line.

In FIG. 7, the discharge portion 134c includes the plurality of first horizontal grooves 150a passing the plurality of second through holes 134b along a substantially horizontal direction, the plurality of first vertical grooves 152a passing the plurality of second through holes 134b along a substantially vertical direction, the plurality of second horizontal grooves 150b at least one between two adjacent first horizontal grooves 150a and the plurality of second vertical grooves 152b at least one between two adjacent first vertical grooves 152a. As a result, the plurality of second through holes 134b are disposed at crossing regions of the plurality of first horizontal grooves 150a and the plurality of first vertical grooves 152a, and the plurality of second horizontal grooves 150b and the plurality of second vertical grooves 152b do not pass the plurality of second through holes 134b. At least one of the plurality of first horizontal grooves 150a and the plurality of second horizontal grooves 150b crosses the plurality of first vertical grooves 152a and the plurality of second vertical grooves 152b. In addition, at least one of the plurality of first vertical grooves 152a and the plurality of second vertical grooves 152b crosses the plurality of first horizontal grooves 150a and the plurality of second horizontal grooves 150b. Accordingly, the discharge portion 134c has a matrix shape.

In another embodiment, the discharge portion may have various shape where the process gas supplied by the plurality of second through holes 134b is induced to be diffused along a substantially lateral direction.

When the process gas is supplied through the plurality of second through holes 134b, the process gas is laterally diffused along the plurality of first horizontal grooves 150a and the plurality of first vertical grooves 152a passing the plurality of second through holes 134b. Further, the process gas is laterally diffused from the plurality of first horizontal grooves 150a and the plurality of first vertical grooves 152a to the plurality of second horizontal grooves 150b and the plurality of second vertical grooves 152b. The process gas supplied to the plurality of first horizontal grooves 150a, the plurality of second horizontal grooves 150b, the plurality of first vertical grooves 152a and the plurality of second vertical grooves 152b is activated to become a plasma and the plasma is supplied onto the susceptor 116 (of FIG. 4).

At least one of the plurality of first through holes 134a may have a height of about 2 mm to about 4 mm and a diameter of about 2 mm to about 3 mm. In addition, at least one of the plurality of second through holes 134b may have a height of about 10 mm to about 12 mm and a diameter of about 0.5 mm. At least one of the plurality of first horizontal grooves 150a, the plurality of second horizontal grooves 150b, the plurality of first vertical grooves 152a and the plurality of second vertical grooves 152b of the discharge portion 134c may have a width of about 3 mm to about 4 mm. In another embodiment, at least one of the plurality of first horizontal grooves 150a and the plurality of first vertical grooves 152a may have a different width from at least one of the plurality of second horizontal grooves 150b and the plurality of second vertical grooves 152b. For example, a width of at least one of the plurality of second horizontal grooves 150b and the plurality of second vertical grooves 152b may be greater than or smaller than a width of at least one of the plurality of first horizontal grooves 150a and the plurality of first vertical grooves 152a based on a lateral diffusion pressure of the process gas supplied from the plurality of second through holes 134b.

The gas distributing means 118 may be manufactured through a first step of providing the plate 118a having the first and second surfaces, a second step of forming the plurality of first through holes 134a on the first surface of the plate 118a, a third step of forming the plurality of second through holes 134b capable of being in fluid communication with the plurality of first through holes 134a and a fourth step of forming the discharge portion 134c of a matrix shape capable of being in fluid communication with the plurality of second through holes 134b on the second surface. In another embodiment, after the discharge portion 134c is formed on the second surface, the plurality of second through holes 134b and the plurality of first through holes 134a may be sequentially formed.

In the substrate processing apparatus 110 of FIGS. 4 to 7, since the discharge portion 134c of the gas distributing means 118 is formed to have a matrix shape, a spray area supplying the process gas is enlarged and the process gas is uniformly supplied to the susceptor 116. In other words, since a spray area of the discharge portion 134c that the process gas occupies is enlarged as compared with the substrate processing apparatus according to the related art, the process gas is uniformly supplied to the susceptor 116 through the discharge portion 134c.

In addition, since the process gas is diffused from at least one of the plurality of second through holes 134b along a substantially lateral direction in the discharge portion 134c, the number of the plurality of second through holes 134b and the plurality of first through holes 134a connected to the plurality of second through holes 134b is reduced as compared with the substrate processing apparatus according to the related art. In other words, since the plurality of second through holes 134b are not disposed at crossing regions of the plurality of second horizontal grooves 150b and the plurality of second vertical grooves 152b in the gas distributing means 118, the number of the plurality of first through holes 134a and the plurality of second through holes 134b may be reduced to a half of the number of the plurality of first through holes and the plurality of second through holes of the substrate processing apparatus according to the related art. As a result, the gas distributing means 118 is more easily manufactured as compared with the substrate processing apparatus according to the related art.

In the discharge portion 134c, the process gas is directly supplied from the plurality of second through holes 134b to the plurality of first horizontal grooves 150a and the plurality of first vertical grooves 152a, and the process gas is indirectly supplied to the plurality of second horizontal grooves 150b and the plurality of second vertical grooves 152b due to the lateral diffusion of the process gas in the plurality of first horizontal grooves 150a and the plurality of first vertical grooves 152a.

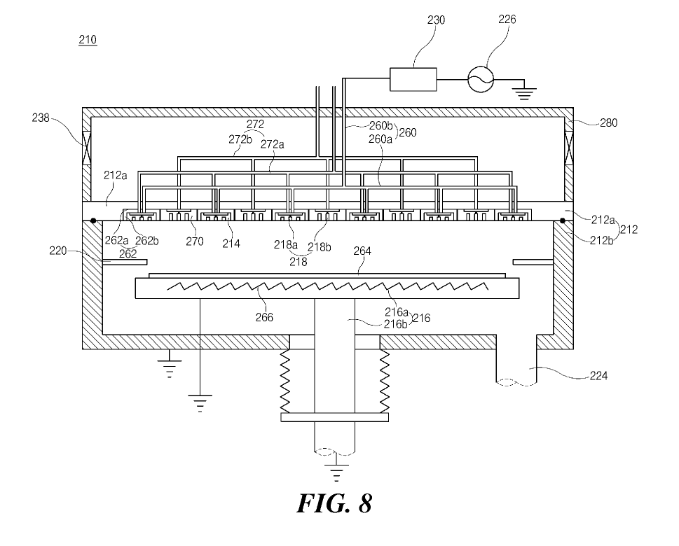

FIG. 8 is a cross-sectional view showing a substrate processing apparatus according to a third embodiment of the present invention.

In FIG. 8, a substrate processing apparatus 210 includes a process chamber 212 providing a reaction space by combination of a chamber lid 212a and a chamber body 212b, a plurality of plasma source electrodes 214 on an inner surface of the chamber lid 212a, a plurality of protruding electrodes 270 combined with the chamber lid 212a between the adjacent plasma source electrodes 214 and used as a plasma ground electrode, a gas distributing means 218 in at least one of the plurality of plasma source electrodes 214 and the plurality of protruding electrodes 270 and a susceptor 216 in the process chamber 212 and having a substrate 264 thereon.

The substrate processing apparatus 210 may further include a gas inlet pipe 272 where the process gas is transmitted to the gas distributing means 218, a feeding line 260 connected to at least one of the plurality of plasma source electrodes 214, a housing 280 over an outer surface of the chamber lid 212a to accommodate the feeding line 260, an edge frame 220 on an inner wall of the process chamber 212 for preventing deposition of a thin film on an edge portion of the substrate 264, a gate valve (not shown) where the substrate 264 is inputted and outputted and an exhaust port 224.

The chamber lid 212a and a chamber body 212b may be combined to each other with an O-ring (not shown) interposed therebetween. The gas distributing means 218 includes a plurality of first gas distributing means 218a respectively in the plurality of plasma source electrodes 214 and a plurality of second gas distributing means 218b respectively in the plurality of protruding electrodes 270. In other words, at least one plasma source electrode 214 functions as the first gas distributing means 218a and at least one protruding electrode 270 functions as the second gas distributing means 218b. When the process gas is supplied to the reaction space, the process gas is activated or ionized between the plurality of plasma source electrodes 214 and the susceptor 216. The gas inlet pipe 272 includes a first gas supplying pipe 272a (of FIG. 10) supplying a first process gas to the plurality of first gas distributing means 218a and a second gas supplying pipe 272b supplying a second process gas to the plurality of second gas distributing means 218b.

A plurality of insulators 262 are formed between the plurality of plasma source electrodes 214 and the chamber lid 212a. The plurality of insulators 262 electrically insulate the plurality of plasma source electrodes 214 from the chamber lid 212a and the plurality of protruding electrodes 270. At least one of the plurality of insulators 262 includes a horizontal portion 262a insulating the plurality of plasma source electrodes 214 from the chamber lid 212a and a vertical portion 262b insulating the plurality of plasma source electrodes 214 from the plurality of protruding electrodes 270. The chamber lid 212a and the plurality of insulators 262 are combined with each other using a connecting means such as a bolt, and similarly, the plurality of insulators 262 are combined with the plurality of plasma source electrodes 214, respectively, using a connecting means such as a bolt.

The plurality of plasma source electrodes 214 are connected to a radio frequency (RF) power supply 226 in parallel by the feeding line 260 electrically connected to the plurality of plasma source electrodes 214. A matcher 230 for impedance matching is connected between the plurality of plasma source electrodes 214 and the RF power supply 226. The RF power supply 226 may use a very high frequency (VHF) wave having a wavelength band of about 20 MHz to about 50 MHz that has excellent plasma generation efficiency. The feeding line 260 includes a plurality of auxiliary feeding lines 260a penetrating the chamber lid 212a and the plurality of insulators 262 and connected to the plurality of plasma source electrodes 214, respectively, and a main feeding line 260b connecting the plurality of auxiliary feeding lines 260a to the RF power supply 226.

The chamber lid 212a may have a rectangular shape and at least one of the plurality of plasma source electrodes 214 may have a stripe shape having longer and shorter axes. The plurality of plasma source electrodes 214 may be disposed to be parallel to each other and spaced apart from each other by the same gap distance. At least one of the plurality of auxiliary feeding lines may be connected to end portions or a central portion of at least one of the plurality of plasma source electrodes 214.

In the substrate processing apparatus 210, while an RF power is supplied from the RF power supply 226 to the plurality of plasma source electrodes 214, the chamber lid 212a, the chamber body 212b, the susceptor 216 and the plurality of protruding electrodes 270 are grounded to be used as a plasma ground electrode. Each of the chamber lid 212a, the chamber body 212b and the susceptor 216 may be formed of a metallic material such as aluminum and stainless steel, and at least one of the plurality of insulators 262 may be formed of a ceramic material such as aluminum oxide.

When the susceptor 216 moves up to be located at a process position, the edge frame 220 on the inner wall of the process chamber 212 blocks the edge portion of the substrate 264 to prevent formation of the thin film on the edge portion of the substrate 264. A reaction gas in the reaction space is outputted through the exhaust port 224 so that a vacuum state of the reaction space can be controlled. A vacuum pump (not shown) may be connected to the exhaust port 224.

The susceptor 216 may include a substrate supporting plate 216a having the substrate 264 thereon and having an area greater than the substrate 264 and a supporting shaft 216b moving up and down the substrate supporting plate 216a. A heater 266 may be formed in the substrate supporting plate 216a for heating up the substrate 264. In the substrate processing apparatus 210, the susceptor 216 may be grounded similarly to the process chamber 212. In another embodiment, an additional RF power may be applied to the susceptor 216 or the susceptor 216 may have an electrically floating state according to conditions of the process for the substrate 264.

For the purpose of preventing a standing wave effect, at least one of the plurality of plasma source electrodes 214 may have a size (width) smaller than a wavelength of an RF wave. Since a standing wave effect is prevented by the plurality of plasma source electrodes 214, a uniform plasma density may be kept in the reaction space.

Further, since the feeding line 260 connected to the RF power supply 226 radiate a heat and the radiated heat is accumulated in a closed space defined by the housing 280 and the chamber lid 212a, the closed space should be cooled. As a result, a cooling means including a plurality of air holes 238 and a plurality of fans (not shown) in the plurality of air holes 238 may be formed in a sidewall of the housing 280. In another embodiment, the closed space may be cooled by various cooling means different from the plurality of air holes 238 and the plurality of fans.

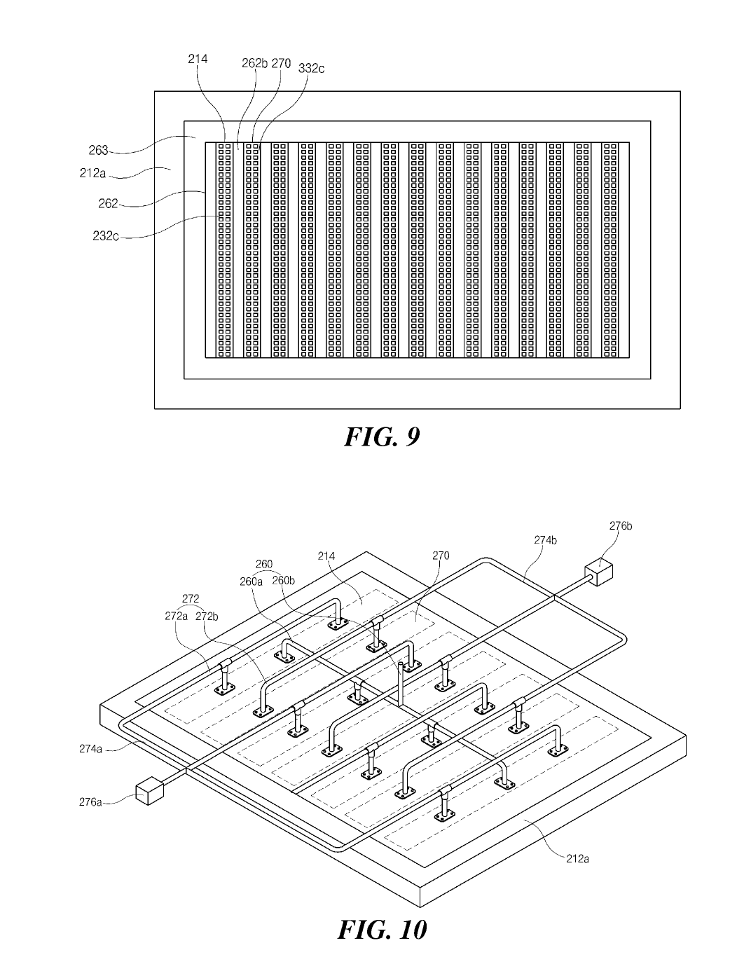

FIG. 9 is a plan view showing a bottom surface of a chamber lid of a substrate processing apparatus according to a third embodiment of the present invention.

In FIG. 9, an outer insulator 263 is formed in a boundary region of the chamber lid 212a. The outer insulator 263 includes a central opening where the plurality of plasma source electrodes 214 and the plurality of protruding electrodes 270. An outermost region of the chamber lid 212a outside the outer insulator 263 is combined with the chamber body 212b (of FIG. 8).

The plurality of insulators 262 are disposed in the central opening on a bottom surface of the chamber lid 212a and spaced apart from each other with the same gap distance. At least one of the plurality of insulators 262 includes the horizontal portion 262a (of FIG. 8) and the vertical portion 262b to provide an insertion portion where at least one of the plurality of plasma source electrodes 214 is inserted and combined. Since the plurality of plasma source electrodes 214 are formed in the insertion portions of the plurality of insulators 262, respectively, the plurality of plasma source electrodes 214 are electrically insulated from the chamber lid 212a.

The plurality of protruding electrodes 270 electrically connected to the chamber lid 212a are formed between the adjacent insulators 262. The plurality of protruding electrodes 270 are electrically insulated from the plurality of plasma source electrodes 214 by the vertical portion 262b of the plurality of insulators 262. The plurality of plasma source electrodes 214 and the plurality of protruding electrodes 270 may alternate with each other. The outer insulator 263 and the plurality of insulators 262 may be formed of a ceramic such as aluminum oxide. The plurality of plasma source electrodes 214 and the plurality of protruding electrodes 270 may be formed of a metallic material such as aluminum.

The plurality of plasma source electrodes 214 and the plurality of protruding electrodes 279 may constitute a single planar surface facing the susceptor 216 (of FIG. 8). In addition, a first discharge portion 232c of the first gas distributing means 218a (of FIG. 8) is formed in at least one of the plurality of plasma source electrodes 214 and a second discharge portion 332c of the second gas distributing means 218b (of FIG. 8) is formed in at least one of the plurality of protruding electrodes 270. The first and second discharge portions 232c and 332c spray the first and second process gases, respectively, and provide a space where a plasma is discharged.

FIG. 10 is a perspective view showing a chamber lid of a substrate processing apparatus according to a third embodiment of the present invention.

In FIG. 10, central portions of the plurality of plasma source electrodes 214 are electrically connected to the plurality of auxiliary feeding lines 260a, respectively, and the plurality of auxiliary feeding lines 260a are electrically connected to the main feeding line 260b in parallel. Further, the main feeding line 260b is electrically connected to the RF power supply 226 (of FIG. 8). The plurality of plasma source electrodes 214 and the plurality of protruding electrodes 270 are designated by a dotted line.

The gas inlet pipe 272 includes the first gas supplying pipe 272a supplying the first process gas to the plurality of first gas distributing means 218a for the plurality of plasma source electrodes 214 and the second gas supplying pipe 272b supplying the second process gas to the plurality of second gas distributing means 218b for the plurality of protruding electrodes 270.

The single first gas supplying pipe 272a may be connected to at least one of the plurality of first gas distributing means 218a and the single second gas supplying pipe 272b may be connected to at least one of the plurality of second gas distributing means 218b. In another embodiment, a plurality of first gas supplying pipes may be connected to at least one of the plurality of first gas distributing means 218a for supplying the first process gas uniformly and a plurality of second gas supplying pipes may be connected to at least one of the plurality of second gas distributing means for supplying the second process gas uniformly.

The plurality of first gas supplying pipes 272a disposed over the chamber lid 212a to correspond to the plurality of plasma source electrodes 214 are connected to a first source part 276a through a first transmitting pipe 274a. The plurality of second gas supplying pipes 272b disposed over the chamber lid 212a to correspond to the plurality of protruding electrodes 270 are connected to a second source part 276b through a second transmitting pipe 274b. The first transmitting pipe 274a is connected to the plurality of first gas supplying pipes 272a in the closed space by the housing 280 (of FIG. 8) and the chamber lid 212a and is connected to the first source part 276a through the sidewall of the housing 280. The second transmitting pipe 274b is connected to the plurality of second gas supplying pipes 272b in the closed space by the housing 280 and the chamber lid 212a and is connected to the second source part 276b through the sidewall of the housing 280.

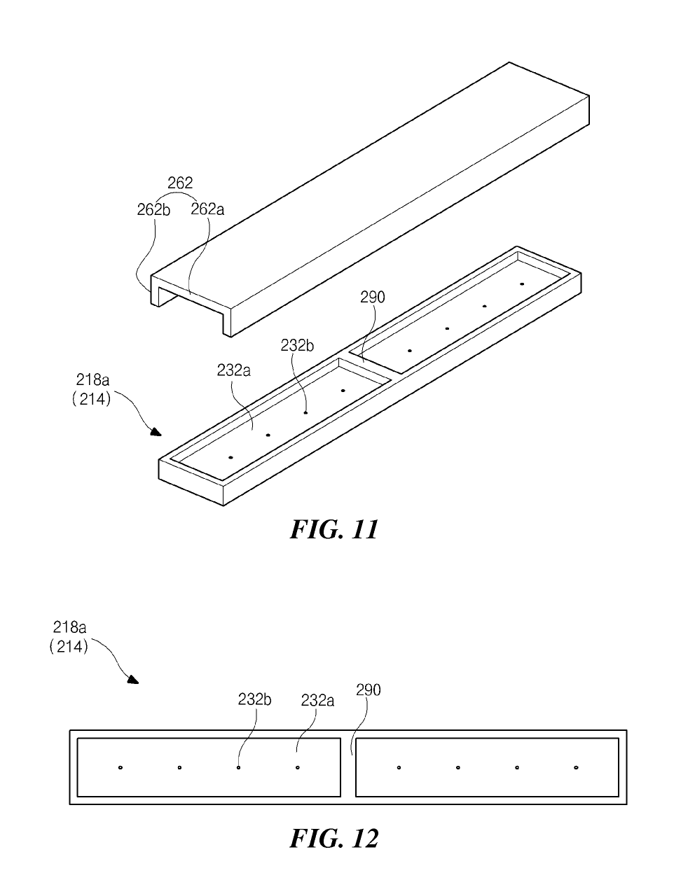

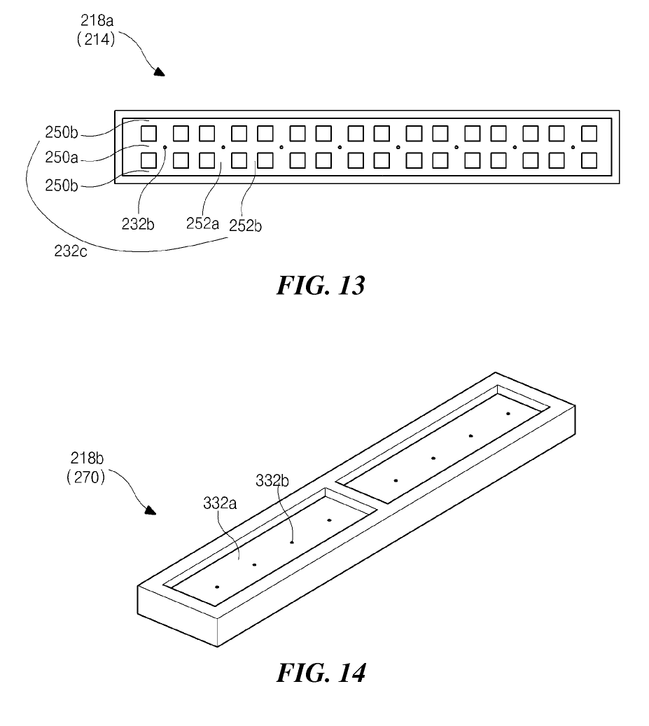

FIG. 11 is an exploded perspective view showing an insulator and a first gas distributing means of a plasma source electrode according to a third embodiment of the present invention, FIG. 12 is a plan view showing a top surface of a first gas distributing means of a plasma source electrode according to a third embodiment of the present invention, and FIG. 13 is a plan view showing a bottom surface of a first gas distributing means of a plasma source electrode according to a third embodiment of the present invention.

In FIGS. 11 to 13, the plasma source electrode 214 includes a first surface contacting the insulator 262 and a second surface facing the susceptor 216. In addition, the first gas distributing means 218a in the plasma source electrode 214 includes a first buffer space 232a capable of accommodating the first process gas transmitted through the first gas supplying pipe 272a (of FIG. 10), a plurality of first through holes 232b uniformly distributed in the plasma source electrode 214 corresponding to the first buffer space 232a and a first discharge portion 232c having a matrix shape and capable of being in fluid communication with the plurality of first through holes 232b. A baffle (not shown) may be formed at a position of the first buffer space 232a corresponding to the first gas supplying pipe 272a to diffuse the first process gas transmitted through the first gas supplying pipe 272a uniformly.

The first buffer space 232a may be defined by a concave portion on the first surface of the plasma source electrode 214. A bridge portion 290 corresponding to a central portion of the plasma source electrode 214 may be formed in the first buffer space 232a and the first buffer space 232a may be divided into two regions by the bridge portion 290. The auxiliary feeding line 260a (of FIG. 10) may be connected to the bridge portion 290 at the central portion of the plasma source electrode 214. In another embodiment, alternatively, the auxiliary feeding line 260a may be connected to two end portions of the plasma source electrode 214.

The plurality of first through holes 232b in the plasma source electrode 214 have a diameter smaller than a width of at least one of a plurality of first horizontal grooves 250a, a plurality of second horizontal grooves 250b, a plurality of first vertical grooves 252a and a plurality of second vertical grooves 252b of the first discharge portion 232c. The first process gas is transmitted from the first gas supplying pipe 272a, and the first discharge portion 232c connected to the plurality of first through holes 232b provides a space where a plasma of the first process gas is discharged. The plurality of first through holes 232b may be disposed along one line. In another embodiment, the plurality of first through holes 232b may be disposed along a plurality of lines according to a width of the plasma source electrode 214.

The first discharge portion 232c includes the plurality of first horizontal grooves 250a passing the plurality of first through holes 232b along a substantially horizontal direction, the plurality of first vertical grooves 252a passing the plurality of first through holes 232b along a substantially vertical direction, the plurality of second horizontal grooves 250b at least one between two adjacent first horizontal grooves 250a, and the plurality of second vertical grooves 252b at least one between two adjacent first vertical grooves 252a.

As a result, the plurality of first through holes 232b are disposed at crossing regions of the plurality of first horizontal grooves 250a and the plurality of first vertical grooves 252a, and the plurality of second horizontal grooves 250b and the plurality of second vertical grooves 252b do not pass the plurality of first through holes 232b. At least one of the plurality of first horizontal grooves 250a and the plurality of second horizontal grooves 250b crosses the plurality of first vertical grooves 252a and the plurality of second vertical grooves 252b. In addition, at least one of the plurality of first vertical grooves 252a and the plurality of second vertical grooves 252b crosses the plurality of first horizontal grooves 250a and the plurality of second horizontal grooves 250b. Accordingly, the first discharge portion 232c may have a matrix shape.

When the first process gas is supplied through the plurality of first through holes 232b, the first process gas is laterally diffused along the plurality of first horizontal grooves 250a and the plurality of first vertical grooves 252a passing the plurality of first through holes 232b. Further, the first process gas is laterally diffused from the plurality of first horizontal grooves 250a and the plurality of first vertical grooves 252a to the plurality of second horizontal grooves 250b and the plurality of second vertical grooves 252b. The first process gas supplied to the plurality of first horizontal grooves 250a, the plurality of second horizontal grooves 250b, the plurality of first vertical grooves 252a and the plurality of second vertical grooves 252b is activated to become a plasma and the plasma is supplied onto the susceptor 216 (of FIG. 8).

When the plasma source electrode 214 has a thickness of about 15 mm, the first buffer space 232a may have a height of about 5 mm and at least one of the plurality of first through holes 232b may have a height of about 3 mm. In addition, the first discharge portion 232c may have a height of about 7 mm. At least one of the plurality of first through holes 232b may have a diameter of about 0.5 mm. At least one of the plurality of first horizontal grooves 250a, the plurality of second horizontal grooves 250b, the plurality of first vertical grooves 252a and the plurality of second vertical grooves 252b of the first discharge portion 232c may have a width of about 3 mm to about 4 mm. In another embodiment, at least one of the plurality of first horizontal grooves 250a and the plurality of first vertical grooves 252a may have a different width from at least one of the plurality of second horizontal grooves 250b and the plurality of second vertical grooves 252b. For example, a width of at least one of the plurality of second horizontal grooves 250b and the plurality of second vertical grooves 252b may be smaller than a width of at least one of the plurality of first horizontal grooves 250a and the plurality of first vertical grooves 252a based on a lateral diffusion pressure of the first process gas supplied from the plurality of first through holes 232b.

The first gas distributing means 218a may be manufactured through a first step of providing the plasma source electrode 214 having the first and second surfaces, a second step of forming the first buffer space 232a on the first surface of the plasma source electrode 214, a third step of forming the plurality of first through holes 232b capable of being in fluid communication with the first buffer space 232a and a fourth step of forming the first discharge portion 232c of a matrix shape capable of being in fluid communication with the plurality of first through holes 232b on the second surface.

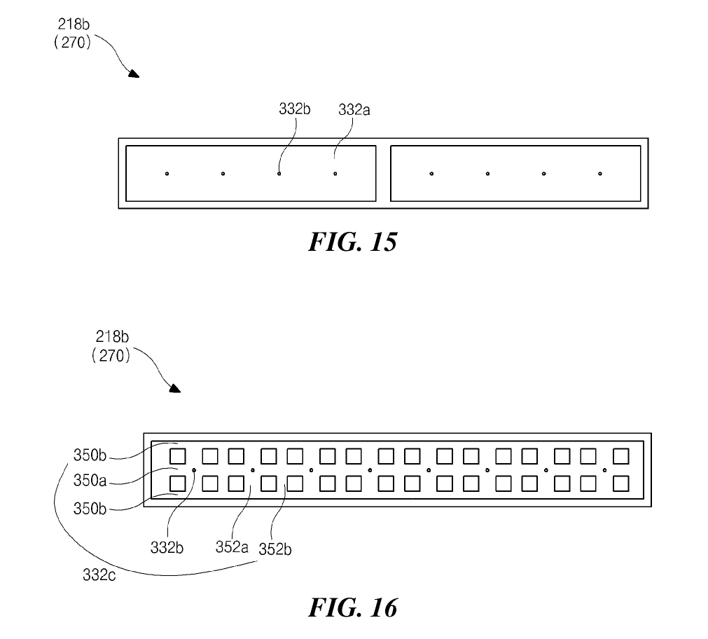

FIG. 14 is a perspective view showing a second gas distributing means of a protruding electrode according to a third embodiment of the present invention, FIG. 15 is a plan view showing a top surface of a second gas distributing means of a protruding electrode according to a third embodiment of the present invention, and FIG. 16 is a plan view showing a bottom surface of a second gas distributing means of a protruding electrode according to a third embodiment of the present invention.

In FIGS. 14 to 16, the protruding electrode 270 includes a first surface facing the chamber lid 212a (of FIG. 8) and a second surface facing the susceptor 216. In addition, the second gas distributing means 218b in the protruding electrode 270 includes a second buffer space 332a capable of accommodating the second process gas transmitted through the second gas supplying pipe 272b (of FIG. 10), a plurality of second through holes 332b uniformly distributed in the protruding electrode 270 corresponding to the second buffer space 332a and a second discharge portion 332c having a matrix shape and capable of being in fluid communication with the plurality of second through holes 332b. A baffle (not shown) may be formed at a position of the second buffer space 332a corresponding to the second gas supplying pipe 272b to diffuse the second process gas transmitted through the second gas supplying pipe 272b uniformly.

The second buffer space 332a may be defined by a concave portion on the first surface of the protruding electrode 270. Although the second buffer space 332a may be divided into two regions in the third embodiment, the second buffer space 332a may not be divided or may be divided into at least three regions in another embodiment.

The plurality of second through holes 332b in the protruding electrode 270 have a diameter smaller than a width of at least one of a plurality of third horizontal grooves 350a, a plurality of fourth horizontal grooves 350b, a plurality of third vertical grooves 352a and a plurality of fourth vertical grooves 352b of the second discharge portion 332c. The second process gas is transmitted from the second gas supplying pipe 272b, and the second discharge portion 332c connected to the plurality of second through holes 332b provides a space where a plasma of the second process gas is discharged. The plurality of second through holes 332b may be disposed along one line. In another embodiment, the plurality of second through holes 332b may be disposed along a plurality of lines according to a width of the protruding electrode 270.

The second discharge portion 332c includes the plurality of third horizontal grooves 350a passing the plurality of second through holes 332b along a substantially horizontal direction, the plurality of third vertical grooves 352a passing the plurality of second through holes 332b along a substantially vertical direction, the plurality of fourth horizontal grooves 350b at least one between two adjacent first horizontal grooves 350a, and the plurality of fourth vertical grooves 352b at least one between two adjacent first vertical grooves 352a.

As a result, the plurality of second through holes 332b are disposed at crossing regions of the plurality of third horizontal grooves 350a and the plurality of third vertical grooves 352a and are not disposed at crossing regions of the plurality of fourth horizontal grooves 350b and the plurality of fourth vertical grooves 352b. At least one of the plurality of third horizontal grooves 350a and the plurality of fourth horizontal grooves 350b crosses the plurality of third vertical grooves 352a and the plurality of fourth vertical grooves 352b. In addition, at least one of the plurality of third vertical grooves 352a and the plurality of fourth vertical grooves 352b crosses the plurality of third horizontal grooves 350a and the plurality of fourth horizontal grooves 350b. Accordingly, the second discharge portion 332c may have a matrix shape.

When the second process gas is supplied through the plurality of second through holes 332b, the second process gas is laterally diffused along the plurality of third horizontal grooves 350a and the plurality of third vertical grooves 352a passing the plurality of third through holes 332b. Further, the second process gas is laterally diffused from the plurality of third horizontal grooves 350a and the plurality of third vertical grooves 352a to the plurality of fourth horizontal grooves 350b and the plurality of fourth vertical grooves 352b. The second process gas supplied to the plurality of third horizontal grooves 350a, the plurality of fourth horizontal grooves 350b, the plurality of third vertical grooves 352a and the plurality of fourth vertical grooves 352b is activated to become a plasma and the plasma is supplied onto the susceptor 216 (of FIG. 8).

A thickness of the protruding electrode 270 may be determined as a sum of a thickness of the insulator 262 and a thickness of the plasma source electrode 214. For example, when the insulator 262 has a thickness of about 5 mm and the plasma source electrode 214 has a thickness of about 15 mm, the protruding electrode 270 may have a thickness of about 20 mm. In addition, the second buffer space 332a may have a height of about 10 mm and at least one of the plurality of second through holes 332b may have a height of about 3 mm. Further, the second discharge portion 332c may have a height of about 7 mm At least one of the plurality of second through holes 332b may have a diameter of about 0.5 mm. At least one of the plurality of third horizontal grooves 350a, the plurality of fourth horizontal grooves 350b, the plurality of third vertical grooves 352a and the plurality of fourth vertical grooves 352b of the second discharge portion 332c may have a width of about 3 mm to about 4 mm. In another embodiment, at least one of the plurality of third horizontal grooves 350a and the plurality of third vertical grooves 352a may have a different width from at least one of the plurality of fourth horizontal grooves 350b and the plurality of fourth vertical grooves 352b. For example, a width of at least one of the plurality of fourth horizontal grooves 350b and the plurality of fourth vertical grooves 352b may be smaller than a width of at least one of the plurality of third horizontal grooves 350a and the plurality of third vertical grooves 352a based on a lateral diffusion pressure of the second process gas supplied from the plurality of second through holes 332b.

Similarly to the first gas distributing means 218a, the second gas distributing means 218b may be manufactured through a first step of providing the protruding electrode 270 having the first and second surfaces, a second step of forming the second buffer space 332a on the first surface of the protruding electrode 270, a third step of forming the plurality of second through holes 332b capable of being in fluid communication with the second buffer space 332a and a fourth step of forming the second discharge portion 332c of a matrix shape capable of being in fluid communication with the plurality of second through holes 332b on the second surface.

Consequently, in a substrate processing apparatus according to the present invention, a spray of a process gas increases and a discharge space for a plasma is provided by a discharge portion having a matrix shape of a gas distributing means. As a result, the process gas is uniformly supplied and the plasma is uniformly generated, thereby a substrate uniformly processed.

In addition, since lateral diffusion of the process gas from a plurality of through holes is induced by a discharge portion having a matrix shape, the number of the plurality of through holes is reduced. For example, the number of the plurality of through holes may be reduced by half as compared with a gas distributing means according to the related art. Specifically, since the number of through holes having a relatively smaller diameter is reduced by half as compared with the gas distributing means according to the related art, manufacturing cost for the gas distributing means is reduced.

It will be apparent to those skilled in the art that various modifications and variations can be made in a substrate processing apparatus of the present invention without departing from the spirit or scope of the invention. Thus, it is intended that the present invention cover the modifications and variations of this invention provided they come within the scope of the appended claims and their equivalents.

What is claimed is:

1. A substrate processing apparatus, comprising:
a process chamber including a chamber lid and a chamber body to provide a reaction space;
a gas distributing means including a plate and an injection part in the process chamber, the injection part including a plurality of through holes in the plate and a discharge portion capable of being in fluid communication with the plurality of through holes, the discharge portion having a matrix shape and providing a space where a plasma is discharged; and
a susceptor in the process chamber, the susceptor facing the gas distributing means.

2. The substrate processing apparatus according to claim 1, wherein the plurality of through holes include a plurality of first through holes and a plurality of second through holes, and a diameter of at least one of the plurality of second through holes is smaller than a diameter of at least one of the plurality of first through holes.

3. The substrate processing apparatus according to claim 2, wherein at least one of the plurality of first through holes and at least one of the plurality of second through holes are coupled with the discharge portion.

4. The substrate processing apparatus according to claim 2, wherein the plate includes first and second surfaces, wherein the gas distributing means includes a buffer space between the first surface of the plate and the chamber lid, wherein the buffer space is adapted to accommodate a process gas and is capable of being in fluid communication with the plurality of first through holes, and wherein the second surface of the plate faces the susceptor.

5. The substrate processing apparatus according to claim 4, wherein the plurality of first through holes extend from the first surface of the plate toward the second surface of the plate, wherein the discharge portion is capable of being in fluid communication with the plurality of second through holes and extends to the second surface of the plate, and wherein the plurality of second through holes are disposed between the plurality of first through holes and the discharge portion.

6. The substrate processing apparatus according to claim 2, wherein the discharge portion comprises:
a plurality of first horizontal grooves passing the plurality of second through holes along a substantially horizontal direction; and
a plurality of first vertical grooves passing the plurality of second through holes along a substantially vertical direction.

7. The substrate processing apparatus according to claim 6, wherein a width of at least one of the plurality of first horizontal grooves and the plurality of first vertical grooves is greater than the diameter of at least one of the plurality of second through holes.

8. The substrate processing apparatus according to claim 7, wherein the discharge portion further comprises:
a plurality of second horizontal grooves between the plurality of first horizontal grooves and not passing the plurality of second through holes; and
a plurality of second vertical grooves between the plurality of first vertical grooves and not passing the plurality of second through holes.

9. The substrate processing apparatus according to claim 8, wherein the width of at least one of the plurality of first horizontal grooves and the plurality of first vertical grooves is different from a width of at least one of the plurality of second horizontal grooves and the plurality of second vertical grooves.

10. A substrate processing apparatus, comprising:
a process chamber including a chamber lid and a chamber body to provide a reaction space;
a plurality of plasma source electrodes on an inner surface of the chamber lid;
a plurality of first gas distributing means in the plurality of plasma source electrodes, respectively, each of the plurality of first gas distributing means including a first buffer space capable of accommodating a first process gas, a plurality of first through holes capable of being in fluid communication with the first buffer space and a first discharge portion capable of being in fluid communication with the plurality of first through holes, the first discharge portion having a matrix shape and providing a first space where a first plasma of the first process gas is discharged; and
a susceptor in the process chamber, the susceptor facing the plurality of plasma source electrodes.

11. The substrate processing apparatus according to claim 10, further comprising a plurality of insulators between the chamber lid and the plurality of plasma source electrodes.

12. The substrate processing apparatus according to claim 11, wherein at least one of the plurality of plasma source electrodes includes first and second surfaces, and wherein the first surface of at least one of the plurality of plasma source electrodes contacts the plurality of insulators and the second surface of each of the plurality of plasma source electrode faces the susceptor.

13. The substrate processing apparatus according to claim 10, wherein the first discharge portion comprises:
a plurality of first horizontal grooves passing the plurality of first through holes along a substantially horizontal direction; and
a plurality of first vertical grooves passing the plurality of first through holes along a substantially vertical direction.

14. The substrate processing apparatus according to claim 13, wherein the first discharge portion further comprises:
a plurality of second horizontal grooves between the plurality of first horizontal grooves and not passing the plurality of first through holes; and
a plurality of second vertical grooves between the plurality of first vertical grooves and not passing the plurality of first through holes.

15. The substrate processing apparatus according to claim 10, further comprising a plurality of protruding electrodes alternating with the plurality of plasma source electrodes and functioning as a ground electrode.

16. The substrate processing apparatus according to claim 11, wherein at least one of the plurality of insulating means includes an insertion portion where each of the plurality of plasma source electrodes is inserted and combined.

17. The substrate processing apparatus according to claim 15, wherein the plurality of plasma source electrode and the plurality of protruding electrodes constitute a single planar surface facing the susceptor.

18. The substrate processing apparatus according to claim 15, wherein a thickness of at least one of the plurality of protruding electrodes is a sum of a thickness of at least one of the plurality of insulating means and a thickness of at least one of the plurality of plasma source electrodes.

19. The substrate processing apparatus according to claim 15, further comprising a plurality of second gas distributing means, at least one of the plurality of second gas distributing means including a second buffer space capable of accommodating a second process gas, a plurality of second through holes capable of being in fluid communication with the second buffer space and a second discharge portion capable of being in fluid communication with the plurality of second through holes, the second discharge portion having a matrix shape and providing a second space where a second plasma of the second process gas is discharged.

20. A gas distributing means for a substrate processing apparatus, comprising:
a plate including first and second surfaces; and
an injection part including a plate and an injection part, wherein the injection part has a plurality of through holes extending from the first surface toward the second surface in the plate and a discharge portion capable of being in fluid communication with the plurality of through holes, the discharge portion having a matrix shape and providing a space where a plasma is discharged.

21. The gas distributing means according to claim 20, wherein the plurality of through holes includes a plurality of first through holes and a plurality of second through holes, and a diameter of at least one of the plurality of second through holes is smaller than a diameter of at least one of the plurality of first through holes.

22. The gas distributing means according to claim 21, wherein at least one of the plurality of first through holes and at least one of the plurality of second through holes are coupled with the discharge portion.

23. The gas distributing means according to claim 20, wherein the discharge portion comprises:
a plurality of first horizontal grooves passing the plurality of through holes along a substantially horizontal direction; and
a plurality of first vertical grooves passing the plurality of through holes along a substantially vertical direction.

24. The gas distributing means according to claim 13, wherein the discharge portion further comprises:
a plurality of second horizontal grooves between the plurality of first horizontal grooves and not passing the plurality of through holes; and
a plurality of second vertical grooves between the plurality of first vertical grooves and not passing the plurality of through holes.

25. A method of manufacturing a gas distributing means for a substrate processing apparatus, the method comprising:
providing a plate having first and second surfaces;
forming a plurality of first through holes extending from the first surface toward the second surface;
forming a plurality of second through holes capable of being in fluid communication with the plurality of first through holes; and
forming a discharge portion capable of being in fluid communication with the plurality of second through holes, the discharge portion having a matrix shape and providing a space where a plasma is discharged.

26. The method according to claim 25, wherein forming the plurality of second through holes are performed before or after forming the discharge portion.
